(19) United States
(12) Patent Application Publication
(10) Pub. No.: US 2022/0223733 A1
(43) Pub. Date: Jul. 14, 2022

(54) High Voltage Device, High Voltage Control Device and Manufacturing Methods Thereof

(71) Applicant: Richtek Technology Corporation, Zhubei City (TW)

(72) Inventors: Chun-Lung Chang, Yilan (TW); Chih-Wen Hsiung, Hsinchu (TW); Kun-Huang Yu, Hsinchu (TW); Kuo-Chin Chiu, Hsinchu (TW); Wu-Te Weng, Hsinchu (TW); Chien-Wei Chiu, Yunlin (TW); Ta-Yung Yang, Taoyuan (TW)

(21) Appl. No.: 17/547,707

(22) Filed: Dec. 10, 2021

Related U.S. Application Data
(60) Provisional application No. 63/135,444, filed on Jan. 8, 2021.

(30) Foreign Application Priority Data
Jul. 21, 2021 (TW) 110126864

(51) Int. Cl. H01L 29/78; H01L 29/66

(52) U.S. Cl. CPC H01L 29/7817; H01L 29/66681

(57) ABSTRACT

A high voltage device includes: a semiconductor layer, a well region, a shallow trench isolation region, a drift oxide region, a body region, a gate, a source, and a drain. The drift oxide region is located on a drift region. The shallow trench isolation region is located below the drift oxide region. A part of the drift oxide region is located vertically above a part of the shallow trench isolation region and is in contact with the shallow trench isolation region. The shallow trench isolation region is formed between the drain and the body region.

### CROSS REFERENCE

The present invention claims priority to U.S. 63/135,444 filed on Jan. 8, 2021, and claims priority to TW 110126864 filed on Jul. 21, 2021.

### BACKGROUND OF THE INVENTION

### Field of Invention

The present invention relates to a high voltage device, a high voltage control device and a method for manufacturing the same, and particularly to a high voltage device, a high voltage control device and a method for manufacturing the same which can enhance breakdown voltage and reduce conduction resistance.

### Description of Related Art

FIGS. 1A and 1B illustrate a cross-sectional diagram and a top-view diagram of a conventional high voltage device 100, respectively. The so-called high voltage device herein refers to a semiconductor device with a drain to which a voltage higher than 3.3V is applied under normal operation. Generally, taking the high voltage device 100 shown in FIGS. 1A and 1B as an example, a drift region 12a (as shown in the dashed-line region in FIG. 1A) is formed between a drain 19 and a body region 16 of the high voltage device 100 to separate the drain 19 from the body region 16. The lateral length of the drift region 12a can be determined according to the operation voltage that the device is designed to withstand under normal operation. As shown in FIGS. 1A and 1B, the high voltage device 100 includes: a well region 12, an insulation structure 13, a drift oxide region 14, the body region 16, a gate 17, a source 18 and the drain 19. The well region 12 has an N conductivity type and is formed above a substrate 11. The insulation structure 13 is a local oxidation of silicon (LOCOS) structure, which serves to define an operation region 13a as the main action region for the high voltage device 100 to operate within. The range of the operation region 13a is indicated by a thick black dashed-line frame in FIG. 1B. As shown in FIG. 1A, a part of the gate 17 is formed above the drift region 12a and covers a part of the drift oxide region 14. Generally, the thickness of the drift oxide region 14 is from about 2,500 Å to about 15,000 Å while the thickness of the gate oxide layer in the gate 17 is from about 20 Å to about 500 Å. The thickness of the drift oxide region 14 is much larger than that of the gate oxide layer, for example at least more than five times the thickness of the gate oxide layer. When the thicker drift oxide region 14 is employed, high level voltage can be blocked during the OFF operation of the high voltage device 100, such that a relatively higher electric field can be formed in the thicker drift oxide region 14, so as to enhance the OFF breakdown voltage of the high voltage device 100. However, although the thicker drift oxide region 14 enhances the withstand voltage of the high voltage device 100 (enhances the OFF breakdown voltage), the conduction resistance and the gate-drain capacitance of the high voltage device 100 are also increased, such that the operation speed is reduced and the performance of the device is reduced.

In view of the above, the present invention proposes a high voltage device, a high voltage control device and a method for manufacturing the same which can enhance the operation speed, reduce the conduction resistance and enhance the breakdown voltage without affecting the thickness of the drift oxide region.

### SUMMARY OF THE INVENTION

In one aspect, the present invention provides a high voltage device including: a semiconductor layer formed on a substrate; a well region having a first conductivity type, wherein the well region is formed in the semiconductor layer; a shallow trench isolation (STI) region formed in the semiconductor layer; a drift oxide region formed on the semiconductor layer, wherein the STI region is located beneath the drift oxide region, and a part of the drift oxide region is located vertically above a part of the STI region and is in contact with the STI region, wherein the drift oxide region is located above a drift region; a body region having a second conductivity type, wherein the body region is formed in the semiconductor layer, and the body region is in contact with the well region in a channel direction; a gate formed on the semiconductor layer, wherein a part of the body region is located vertically beneath and in contact with the gate, so as to provide an inversion current channel during an ON operation of the high voltage device, and a part of the gate is located vertically above and in contact with the drift oxide region; and a source and a drain having the first conductivity type, wherein the source and the drain are formed in the semiconductor layer, wherein the source and the drain are located below the gate at two sides of the gate respectively, wherein the source is located in the body region, and the drain is located in the well region and away from the body region, wherein the drift region is located in the well region between the drain and the body region in the channel direction and serves as a drift current channel during the ON operation of the high voltage device; wherein the STI region is formed between the drain and the body region.

In another aspect, the present invention provides a method for manufacturing a high voltage device, the method including: forming a semiconductor layer on a substrate; forming a well region in the semiconductor layer, wherein the well region has a first conductivity type; forming at least one shallow trench isolation (STI) region in the semiconductor layer; forming a drift oxide region on the semiconductor layer, wherein the STI region is located beneath the drift oxide region, and a part of the drift oxide region is located vertically above a part of the STI region and is in contact with the STI region, wherein the drift oxide region is located above a drift region; forming a body region having a second conductivity type in the semiconductor layer, wherein the body region is in contact with the well region in a channel direction; forming a gate on the semiconductor layer, wherein a part of the body region is located vertically beneath and in contact with the gate, so as to provide an inversion current channel during an ON operation of the high voltage device, and a part of the gate is located vertically above and in contact with the drift oxide region; and forming a source and a drain in the semiconductor layer, wherein the source and the drain are located below the gate at two sides of the gate respectively, wherein the source is located in the body region, and the drain is located in the well region and away from the body region, wherein the drift region is located in the well region between the drain and the body region in the channel direction and serves as a drift current channel during the ON operation of the high voltage device; wherein the STI region is formed between the drain and the body region.

In still another aspect, the present invention provides a high voltage control device including: a semiconductor layer formed on a substrate; a drift well region having a first conductivity type, wherein the drift well region is formed in the semiconductor layer; a channel well region having a second conductivity type, wherein the channel well region is formed in the semiconductor layer, and the channel well region is in contact with the drift well region in a channel direction; a shallow trench isolation (STI) region formed in the semiconductor layer; a drift oxide region formed on the semiconductor layer, wherein the STI region is located beneath the drift oxide region, and a part of the drift oxide region is located vertically above a part of the STI region and is in contact with the STI region, wherein the drift oxide region is located above a drift region; a gate formed on the semiconductor layer, wherein a part of the channel well region is located vertically beneath and in contact with the gate, so as to provide an inversion current channel during an ON operation of the high voltage control device, and a part of the gate is located vertically above and in contact with the drift oxide region; a source and a drain having the first conductivity type, wherein the source and the drain are formed in the semiconductor layer, wherein the source and the drain are located below the gate at two sides of the gate respectively, wherein the source is located in the channel well region, and the drain is located in the drift well region and away from the channel well region, wherein the drift region is located in the drift well region between the drain and the channel well region in the channel direction and serves as a drift current channel during the ON operation of the high voltage control device; a channel well contact having the second conductivity type, wherein the channel well contact is formed in the channel well region and serves as an electrical contact of the channel well region, wherein the channel well contact is formed beneath and in contact with a top surface of the semiconductor layer in a vertical direction; and a channel isolation region formed in the semiconductor layer and between the source and the channel well contact, wherein the channel isolation region is formed beneath and in contact with the top surface; wherein the STI region is formed between the drain and the channel well region.

In yet another aspect, the present invention provides a method for manufacturing a high voltage control device, the method including: forming a semiconductor layer on a substrate; forming a drift well region in the semiconductor layer, wherein the drift well region has a first conductivity type; forming a channel well region having a second conductivity type in the semiconductor layer, wherein the channel well region is in contact with the drift well region in a channel direction; forming at least one shallow trench isolation (STI) region in the semiconductor layer and forming a channel isolation region in the semiconductor layer, wherein the channel isolation region is formed beneath and in contact with a top surface of the semiconductor layer; forming a drift oxide region on the semiconductor layer, wherein the STI region is located beneath the drift oxide region, and a part of the drift oxide region is located vertically above a part of the STI region and is in contact with the STI region, wherein the drift oxide region is located above a drift region; forming a gate on the semiconductor layer, wherein a part of the channel well region is located vertically beneath and in contact with the gate, so as to provide an inversion current channel during an ON operation of the high voltage control device, and a part of the gate is located vertically above and in contact with the drift oxide region; forming a source and a drain in the semiconductor layer, wherein the source and the drain are located below the gate at two sides of the gate respectively, wherein the source is located in the channel well region, and the drain is located in the drift well region and away from the channel well region, wherein the drift region is located in the drift well region between the drain and the channel well region in the channel direction and serves as a drift current channel during the ON operation of the high voltage control device; and forming a channel well contact in the channel well region, wherein the channel well contact has the second conductivity type and serves as an electrical contact of the channel well region, wherein the channel well contact is formed beneath and in contact with the top surface in a vertical direction; wherein the STI region is formed between the drain and the channel well region, wherein the channel isolation region is formed between the source and the channel well contact.

In one embodiment, the drift oxide region includes a local oxidation of silicon (LOCOS) structure or a chemical vapor deposition (CVD) oxide region.

In one embodiment, the STI region is in contact with the drain in the channel direction.

In one embodiment, the semiconductor layer is a P-type epitaxial silicon layer with a resistance of 45 Ohm-cm.

In one embodiment, the drift oxide region includes the CVD oxide region with a thickness of 400 Å-450 Å.

In one embodiment, the high voltage device is a laterally diffused metal oxide semiconductor (LDMOS) device with a gate driving voltage of 3.3V and a gate oxide thickness of 80 Å-100 Å.

In one embodiment, a low voltage device is formed on the substrate, and the low voltage device has a channel length of 0.18 μm.

In one embodiment, the body region is formed by a self-aligned process step, wherein the self-aligned process step includes: etching a poly silicon layer to form a conductive layer of the gate; and using the conductive layer as a mask and forming the body region by an ion implantation step.

Advantages of the present invention include that the conduction resistance of the high voltage device can be reduced and the breakdown voltage of the high voltage device can be enhanced.

Another advantage of the present invention is that the high voltage device of the present invention can be manufactured by a standard high voltage device manufacturing process without the need of an additional lithography process step, so the manufacturing cost does not increase as compared with the prior art.

The objectives, technical details, features, and effects of the present invention will be better understood with regard to the detailed description of the embodiments below, with reference to the attached drawings.

### BRIEF DESCRIPTION OF THE DRAWINGS

FIGS. 1A and 1B illustrate a cross-sectional diagram and a top view diagram of a conventional high voltage device respectively.

FIGS. 2A and 2B illustrate a cross-sectional diagram and a top view diagram of a high voltage device in accordance with one embodiment of the present invention.

FIGS. 3A and 3B illustrate a cross-sectional diagram and a top view diagram of a high voltage device in accordance with another embodiment of the present invention.

FIGS. 4A and 4B illustrate a cross-sectional diagram and a top view diagram of a high voltage control device in accordance with still another embodiment of the present invention.

FIGS. 5A-5H illustrate diagrams showing a method for manufacturing a high voltage device in accordance with one embodiment of the present invention.

FIGS. 6A-6I illustrate diagrams showing a method for manufacturing a high voltage control device in accordance with another embodiment of the present invention.

FIG. 7 illustrates a schematic diagram of forming a body region 26 of a high voltage device in accordance with another embodiment of the present invention.

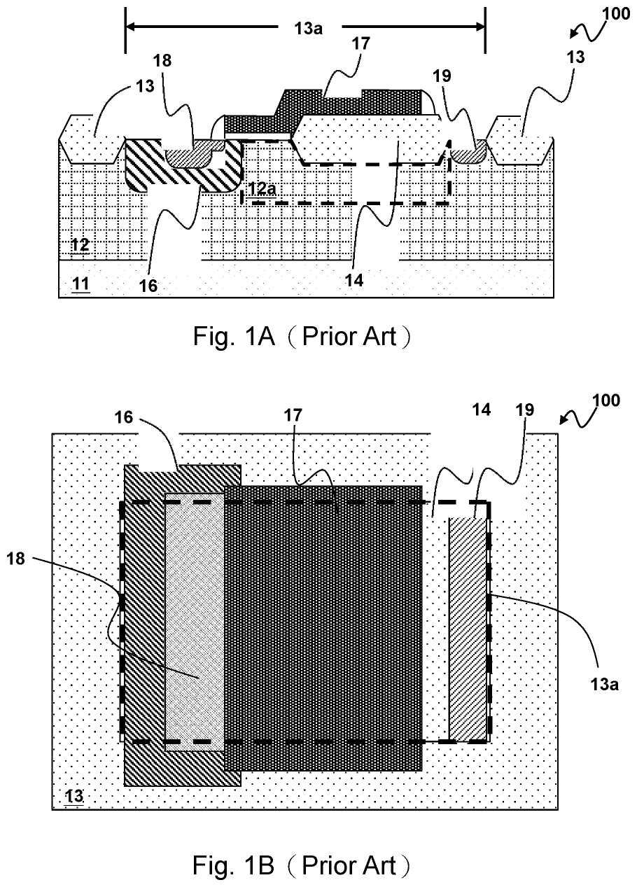

### DESCRIPTION OF THE PREFERRED EMBODIMENTS

The drawings as referred to throughout the description of the present invention are for illustration only, to show the interrelations among the process steps and the layers, but the shapes, thicknesses, and widths are not drawn in actual scale.

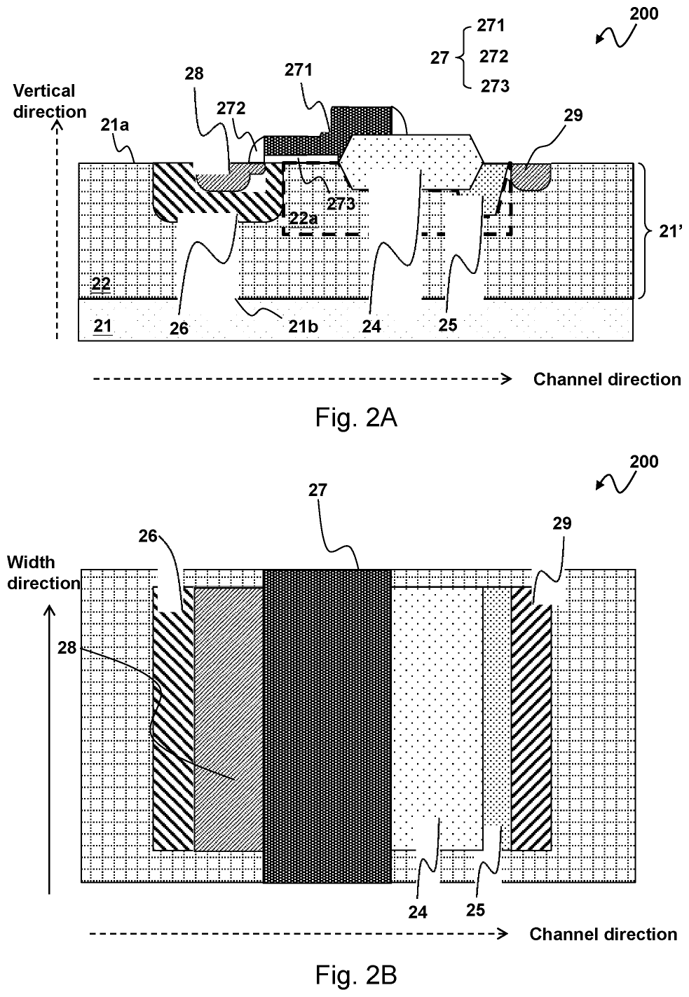

Please refer to FIGS. 2A And 2B, which illustrate a cross-sectional diagram and a top view diagram of a high voltage device 200 in accordance with one embodiment of the present invention. As shown in FIGS. 2A and 2B, the high voltage device 200 includes a semiconductor layer 21′, a well region 22, a drift oxide region 24, a shallow trench isolation (STI) region 25, a body region 26, a gate 27, a source 28 and a drain 29. The semiconductor layer 21′ is formed on the substrate 21. The semiconductor layer 21′ has a top surface 21a and a bottom surface 21b opposite to the top surface 21a in a vertical direction (as indicated by the direction of the dashed arrow in FIG. 2A). The substrate 21 is, for example but not limited to, a P-type or N-type semiconductor substrate. The semiconductor layer 21′, for example, is formed on the substrate 21 by an epitaxial process step, or is a part of the substrate 21. The semiconductor layer 21′ can be formed by various methods known to a person having ordinary skill in the art, so the details thereof are not redundantly explained here. In one preferable embodiment, the semiconductor layer 21′ is a P-type epitaxial silicon layer with a resistance of 45 Ohm-cm. In one preferable embodiment, the high voltage device 200 is a laterally diffused metal oxide semiconductor (LDMOS) device as shown in FIGS. 2A and 2B with a gate driving voltage of 3.3V and a gate oxide thickness of 80 Å-100 Å.

Still referring to FIGS. 2A and 2B, the STI region 25 is formed in the semiconductor layer 21′. The drift oxide region 24 is formed on the semiconductor layer 21′ and is located above the drift region 22a (as indicated by the dashed-line frame in FIG. 2A). The STI region 25 is located below the drift oxide region 24, and a part of the drift oxide region 24 is located vertically above a part of the STI region 25 and is in contact with the STI region 25. In one embodiment, the drift oxide region 24 is, for example but not limited to, the local oxidation of silicon (LOCOS) structure shown in FIG. 2A; in another embodiment, it can be a chemical vapor deposition (CVD) oxide region. In one preferable embodiment, the drift oxide region 24 includes the CVD oxide region with a thickness of 400 Å-450 Å.

The well region 22 has the first conductivity type, and is formed in the semiconductor layer 21′. The well region 22 is located beneath the top surface 21a and is in contact with the top surface 21a in the vertical direction. The well region is formed by for example one or more ion implantation process steps. The body region 26 has a second conductivity type, and is formed in the well region 22. The body region 26 is located beneath and in contact with the top surface 21a in the vertical direction. The body region 26 is in contact with the well region 22 in a channel direction (as indicated by the direction of the dashed arrow in FIG. 2B). The gate 27 is formed on the top surface 21a of the semiconductor layer 21′. The gate 27 is substantially in a rectangular shape which extends along a width direction (as indicated by the direction of the solid arrow in FIG. 2B) when viewed from the top view. A part of the body region 26 is located vertically below the gate 27 and is in contact with the gate 27 in the vertical direction, so as to provide an inversion current channel in the ON operation of the high voltage device 200. A part of the gate 27 is located vertically above and in contact with the drift oxide region 24. A conductive layer 271 of the gate 27 is doped with first conductivity type impurities and has the first conductivity type. The conductive layer 271 of the gate 27 is, for example but not limited to, a polysilicon structure doped with the first conductivity type impurities. In one preferable embodiment, the body region 26 is formed by a self-aligned process step, wherein the self-aligned process step includes: etching a poly silicon layer to form a conductive layer 271 of the gate 27; and using the conductive layer 271 as a mask and forming the body region 26 by an ion implantation step.

The source 28 and the drain 29 have the first conductivity type. The source 28 and the drain 29 are formed beneath the top surface 21a and in contact with the top surface 21a in the vertical direction when viewed from the cross-sectional diagram of FIG. 2A. The source 28 and the drain 29 are located at two different sides out of the gate 27 respectively, wherein the source 28 is located in the body region 26, and the drain 29 is located in the well region 22 which is away from the body region 26. In the channel direction, part of the well region 22 which is near the top surface 21a, and between the body region 26 and the drain 29, defines the drift region 22a. The drift region 22a separates the drain 29 from the body region 26. The drift region 22a serves as a drift current channel in the ON operation of the high voltage device 200. In one embodiment, the STI region 25 is formed between the drain 29 and the body region 26. As shown in FIG. 2A, the STI region 25 is in contact with the drain 29 in the channel direction.

In one preferable embodiment, a low voltage device is formed on the substrate 21, and the low voltage device has a channel length of 0.18 μm.

Compared with the prior art, in the high voltage device and the high voltage control device according to the present invention, the insulation structure between the body region 26 and the drain 29 further includes the STI region in addition to the drift oxide region, and at least a portion of the STI region overlaps with the drift oxide region in a projection viewed along the vertical direction, whereby the total thickness of the oxide regions above part of the drift region is increased. When the conduction current of the high voltage device or the high voltage control device flows through the drift region, the conduction current must flow downwards to pass under the bottom of the STI region, so the length of the current path is prolonged. Furthermore, when the high voltage device or the high voltage control device operates, the electric field does not concentrate on the surfaces near the drain, so the electric field distribution can be expanded. All of the above contribute to enhancing the breakdown voltage. Moreover, the high voltage device or the high voltage control device according to the present invention has a reduced size (under the same specification of electrical parameters) because of the relatively higher breakdown voltage, so the conduction resistance can be reduced due to the size reduction.

Note that the term “inversion current channel” means thus. Taking this embodiment as an example, when the high voltage device 200 operates in the ON operation due to the voltage applied to the gate 27, an inversion layer is formed beneath the gate 27, so that the conduction current flows through the region of the inversion layer, which is the inversion current channel known to a person having ordinary skill in the art.

Note that the term “drift current channel” means thus. Taking this embodiment as an example, the drift region provides a region where the conduction current passes through in a drifting manner when the semiconductor device 200 operates in the ON operation, and the current path through the drift region is referred to as the “drift current channel”, which is known to a person having ordinary skill in the art, so the details thereof are not redundantly explained here.

Note that the top surface 21a as defined in the context of this invention does not mean a completely flat plane but refers to a surface of the semiconductor layer 21′. In the present embodiment, for example, where the top surface 21a is in contact with the drift oxide region 24 is recessed.

Note that the gate 27 as defined in the context of this invention includes: a conductive layer 271 which is conductive, a dielectric layer 273 in contact with the top surface 21a, and a spacer layer 272 which is electrically insulative. The dielectric layer 273 is formed on the body region 26 and the well region 22, and is in contact with the body region 26 and the well region 22. The conductive layer 271 serves as an electrical contact of the gate 27, and is formed on the dielectric layer 273 and in contact with the dielectric layer 273. The spacer layer 272 is formed out of two sides of the conductive layer 271, as an electrically insulative layer of the gate 27. The gate 27 is known to a person having ordinary skill in the art, and the detailed descriptions thereof are thus omitted.

Note that the above-mentioned “first conductivity type” and “second conductivity type” indicate different conductivity types of impurities which are doped in regions or layers of the high voltage device (such as but not limited to the aforementioned well region, body region and source and the drain, etc.), so that the doped region or layer has the first or second conductivity type; the first conductivity type for example is N-type, and the second conductivity type is P-type, or the opposite. The first conductivity type and the second conductivity type are conductivity types which are opposite to each other.

In addition, note that the term “high voltage” device means that, when the device operates in normal operation, the voltage applied to the drain is higher than a specific voltage, such as 3.3V; for devices of different high voltages, a lateral distance (distance of the drift region 22a) between the body region 26 and the drain 29 can be determined according to the operation voltage that the device is designed to withstand during normal operation, which is known to a person having ordinary skill in the art.

Note that the term “low voltage” device means that, when the device operates in normal operation, the voltage applied to the drain is lower than a specific voltage, such as 3.3V.

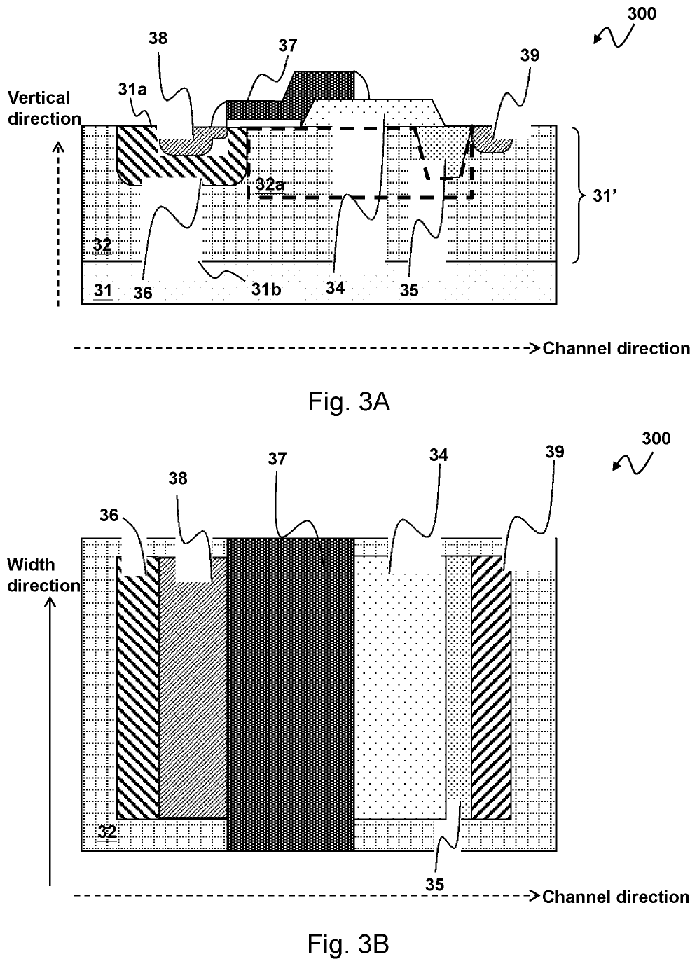

FIGS. 3A and 3B illustrate a cross-sectional diagram and a top view diagram of a high voltage device 300 in accordance with another embodiment of the present invention. The difference between the present embodiment and the embodiment of FIGS. 2A and 2B is that the drift oxide region of the present embodiment is the CVD oxide region. The substrate 31, the semiconductor layer 31′, the well region 32, the STI region 35, the body region 36, the gate 37, the source 38 and the drain 39 of the present embodiment are similar to the substrate 21, the semiconductor layer 21′, the well region 22, the STI region 25, the body region 26, the gate 27, the source 28 and the drain 29 of FIGS. 2A and 2B, so they are not redundantly explained again.

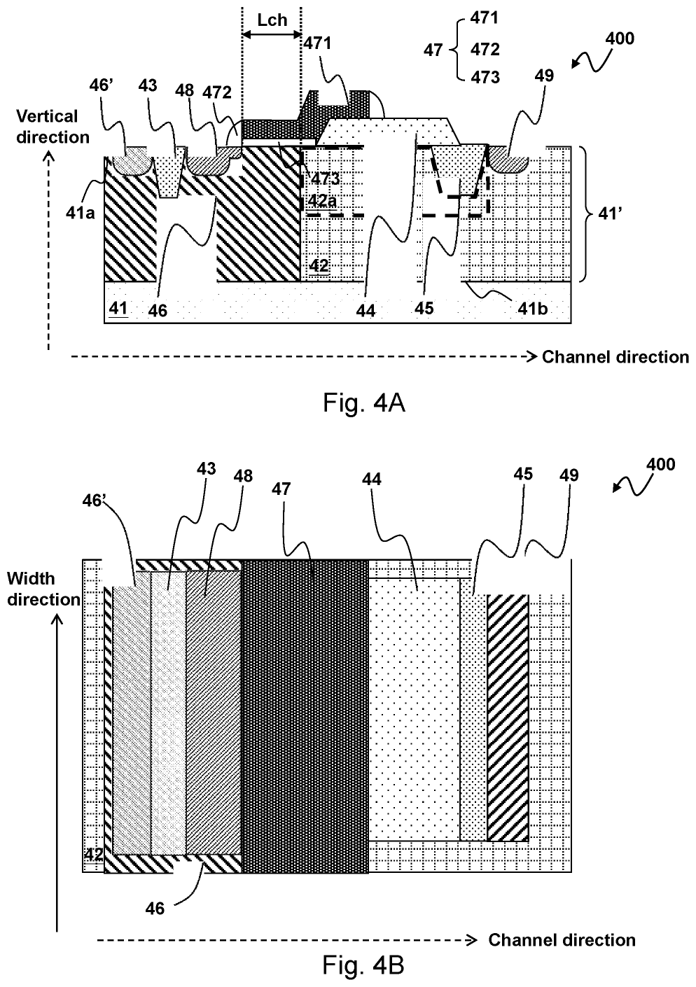

FIGS. 4A and 4B illustrate a cross-sectional diagram and a top view diagram of a high voltage control device 400 in accordance with still another embodiment of the present invention. The high voltage control device 400 includes: a semiconductor layer 41′, a drift well region 42, a channel isolation region 43, a drift oxide region 44, a shallow trench isolation (STI) region 45, a channel well region 46, a channel well contact 46′, a gate 47, a source 48 and a drain 49. The semiconductor layer 41′ is formed on the substrate 41. The semiconductor layer 41′ has a top surface 41a and a bottom surface 41b opposite to the top surface 41a in a vertical direction (as indicated by the direction of the dashed arrow in FIG. 4A). The substrate 41 is, for example but not limited to, a P-type or N-type semiconductor substrate. The semiconductor layer 41′, for example, is formed on the substrate 41 by an epitaxial process step, or is a part of the substrate 41. The semiconductor layer 41′ can be formed by various methods known to a person having ordinary skill in the art, so the details thereof are not redundantly explained here. In one preferable embodiment, the semiconductor layer 41′ is a P-type epitaxial silicon layer with a resistance of 45 Ohm-cm. In one preferable embodiment, the high voltage device 400 is a laterally diffused metal oxide semiconductor (LDMOS) device as shown in FIGS. 4A and 4B with a gate driving voltage of 3.3V and a gate oxide thickness of 80 Å-100 Å.

Still referring to FIGS. 4A and 4B, the STI region 45 is formed in the semiconductor layer 41′. The drift oxide region 44 is formed on the semiconductor layer 41′ and is located above the drift region 42a (as indicated by the dashed-line frame in FIG. 4A). The STI region 45 is located below the drift oxide region 44, and a part of the drift oxide region 44 is located vertically above a part of the STI region 45 and is in contact with the STI region 45. In one embodiment, the drift oxide region 44 is for example the chemical vapor deposition (CVD) oxide region shown in FIG. 4A; in another embodiment, it can be a local oxidation of silicon (LOCOS) structure. In one preferable embodiment, the drift oxide region 44 includes the CVD oxide region with a thickness of 400 Å-450 Å.

The drift well region 42 has the first conductivity type, and is formed in the semiconductor layer 41′. The drift well region 42 is located beneath the top surface 41a and is in contact with the top surface 41a in the vertical direction. The drift well region 42 is formed by for example at least one ion implantation process step. The channel well region 46 has a second conductivity type, and is formed in the semiconductor layer 41′. The channel well region 46 is located beneath and in contact with the top surface 41a in the vertical direction. The channel well region 46 is formed by for example at least one ion implantation process step. The drift well region 42 is in contact with the channel well region 46 in a channel direction (as indicated by the direction of the dashed arrow in FIG. 4A). The gate 47 is formed on the top surface 41a of the semiconductor layer 41′. The gate 47 is substantially in a rectangular shape which extends along a width direction (as indicated by the direction of the solid arrow in FIG. 4B) when viewed from the top view. A part of the channel well region 46 is located vertically below the gate 47 and is in contact with the gate 47 in the vertical direction, so as to provide an inversion current channel in the ON operation of the high voltage control device 400. A part of the gate 47 is located vertically above and in contact with the drift oxide region 44. A conductive layer 471 of the gate 47 is doped with first conductivity type impurities and has the first conductivity type. The conductive layer 471 of the gate 47 is, for example but not limited to, a polysilicon structure doped with the first conductivity type impurities.

The source 48 and the drain 49 have the first conductivity type. The source 48 and the drain 49 are formed beneath the top surface 41a and in contact with the top surface 41a in the vertical direction when viewed from the cross-sectional diagram of FIG. 4A. The source 48 and the drain 49 are located at two different sides out of the gate 47 respectively, wherein the source 48 is located in the channel well region 46, and the drain 49 is located in the drift well region 42 which is away from the channel well region 46. In the channel direction, part of the drift well region 42 which is near the top surface 41a, and between the channel well region 46 and the drain 49, defines the drift region 42a. The drift region 42a separates the drain 49 from the channel well region 46. The drift region 42a serves as a drift current channel in the ON operation of the high voltage control device 400. In one embodiment, the STI region 45 is formed between the drain 49 and the channel well region 46. As shown in FIG. 4A, the STI region 45 is in contact with the drain 49 in the channel direction. As shown in FIG. 4A, in one embodiment, a distance Lch from the interface between the channel well region 46 and the drift well region 42 to the edge of the source 48 can be adjusted.

Referring to FIG. 4A, the channel well contact 46′ has the second conductivity type and is formed in the channel well region 46 as the electrical contact of the channel well region 46. The channel well contact 46′ is formed beneath and in contact with the top surface 41a of the semiconductor layer 41′ in the vertical direction. The channel isolation region 43 is formed in the channel well region 46 and between the source 48 and the channel well contact 46′. The channel isolation region 43 is formed beneath and in contact with the top surface 41a. In one embodiment, the channel isolation region 43 is for example the STI structure.

In one preferable embodiment, a low voltage device is formed on the substrate 41, and the low voltage device has a channel length of 0.18 μm.

Note that the term “inversion current channel” means thus. Taking this embodiment as an example, when the high voltage control device 400 operates in the ON operation due to the voltage applied to the gate 47, an inversion layer is formed beneath the gate 47, so that the conduction current flows through the region of the inversion layer, which is the inversion current channel known to a person having ordinary skill in the art.

Note that the term “drift current channel” means thus. Taking this embodiment as an example, the drift region provides a region where the conduction current passes through in a drifting manner when the semiconductor device 400 operates in the ON operation, and the current path through the drift region is referred to as the “drift current channel”, which is known to a person having ordinary skill in the art, so the details thereof are not redundantly explained here.

Note that the top surface 41a as defined in the context of this invention does not mean a completely flat plane but refers to a surface of the semiconductor layer 41′. In one embodiment, if the drift oxide region 44 is the LOCOS structure, where the top surface 41a is in contact with the drift oxide region 44 is recessed.

Note that the gate 47 as defined in the context of this invention includes: a conductive layer 471 which is conductive, a dielectric layer 473 in contact with the top surface 41a, and a spacer layer 472 which is electrically insulative. The dielectric layer 473 is formed on the channel well region 46 and the drift well region 42, and is in contact with the channel well region 46 and the drift well region 42. The conductive layer 471 serves as an electrical contact of the gate 47, and is formed on the dielectric layer 473 and in contact with the dielectric layer 473. The spacer layer 472 is formed out of two sides of the conductive layer 471, as an electrically insulative layer of the gate 47. The gate 47 is known to a person having ordinary skill in the art, and the detailed descriptions thereof are thus omitted.

Note that the above-mentioned “first conductivity type” and “second conductivity type” indicate different conductivity types of impurities which are doped in regions or layers of the high voltage control device (such as but not limited to the aforementioned drift well region, channel well region and source and the drain, etc.), so that the doped region or layer has the first or second conductivity type; the first conductivity type for example is N-type, and the second conductivity type is P-type, or the opposite. The first conductivity type and the second conductivity type are conductivity types which are opposite to each other.

In addition, note that the term “high voltage” control device means that, when the device operates in normal operation, the voltage applied to the drain is higher than a specific voltage, such as 3.3V; for devices of different high voltages, a lateral distance (distance of the drift region 42a) between the channel well region 46 and the drain 49 can be determined according to the operation voltage that the device is designed to withstand during normal operation, which is known to a person having ordinary skill in the art.

Note that the term “low voltage” device means that, when the device operates in normal operation, the voltage applied to the drain is lower than a specific voltage, such as 3.3V.

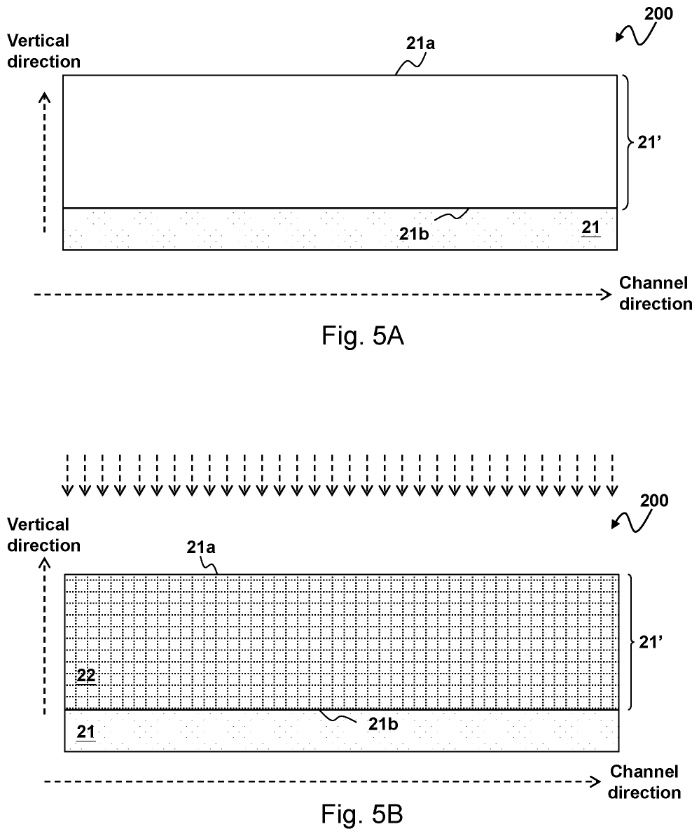

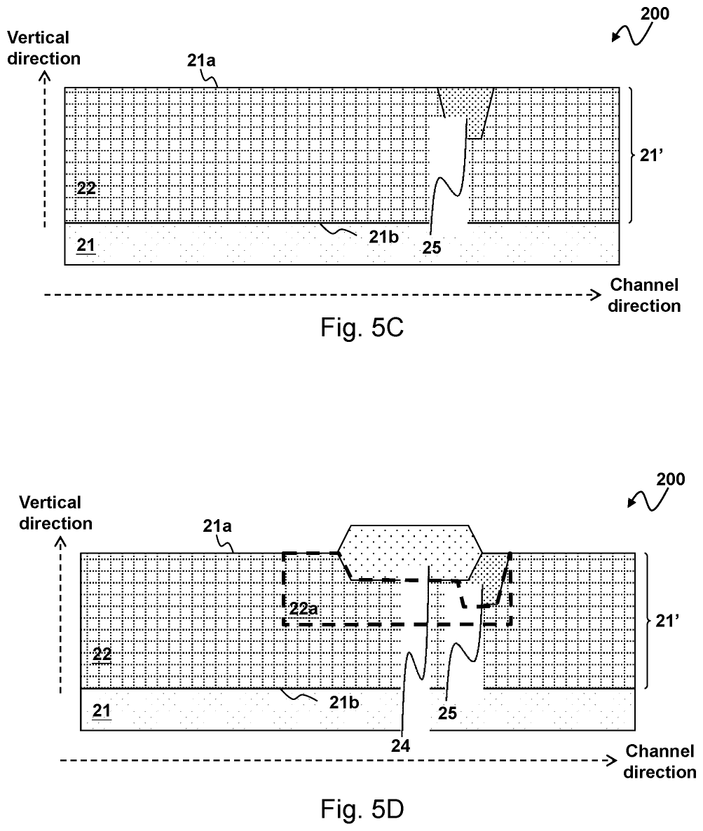

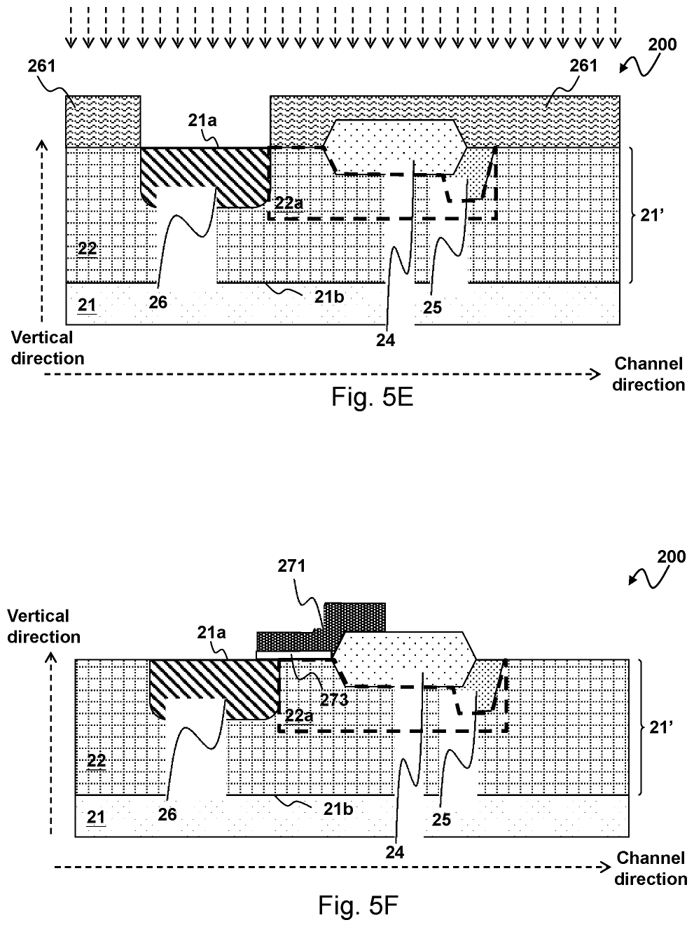

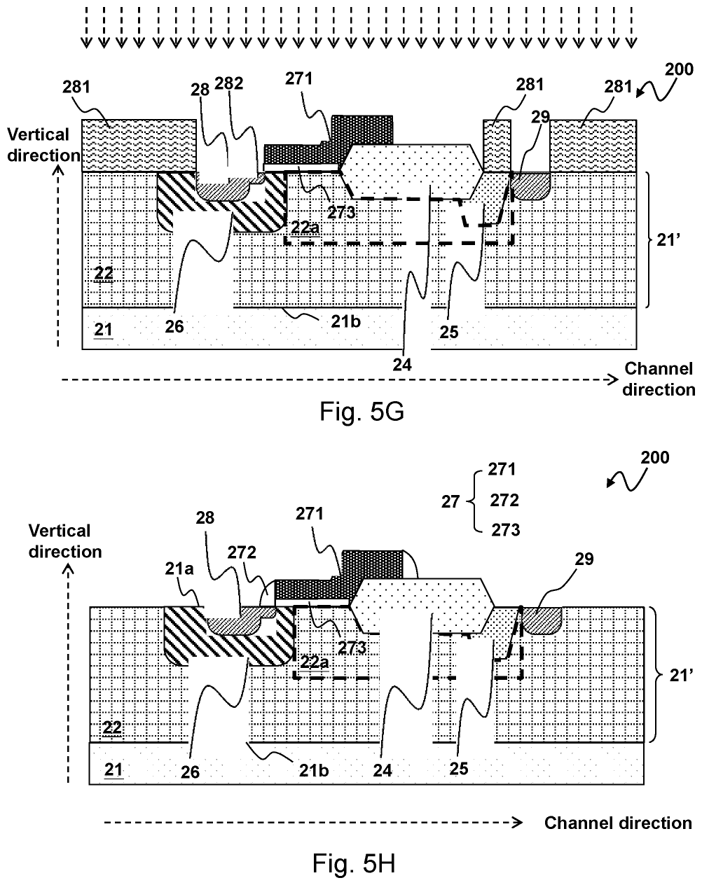

Please refer to FIGS. 5A-5H, which illustrate diagrams showing a method for manufacturing a high voltage device 200 in accordance with one embodiment of the present invention. As shown in FIG. 5A, first, a semiconductor layer 21′ is formed on a substrate 21. The semiconductor layer 21′, for example, is formed on the substrate 21 by an epitaxial process step, or is a part of the substrate 21. The semiconductor layer 21′ has a top surface 21a and a bottom surface 21b opposite to the top surface 21a in a vertical direction (as indicated by the direction of the dashed arrow in FIG. 5A). The semiconductor layer 21′ can be formed by various methods known to a person having ordinary skill in the art, so the details thereof are not redundantly explained here. The substrate 21 is, for example but not limited to, a P-type or N-type semiconductor substrate. In one preferable embodiment, the semiconductor layer 21′ is a P-type epitaxial silicon layer with a resistance of 45 Ohm-cm. In one preferable embodiment, the high voltage device 200 is a laterally diffused metal oxide semiconductor (LDMOS) device as shown in FIGS. 2A and 2B with a gate driving voltage of 3.3V and a gate oxide thickness of 80 Å-100 Å.

Subsequently, please refer to FIG. 5B. A well region 22 can be formed by doping impurities of the first conductivity type into the semiconductor layer 21′ in the form of accelerated ions by, for example but not limited to, one or more ion implantation process steps. At this stage, the drift oxide region 24 has not been formed yet, and therefore the top surface 21a is not completely defined yet. The well region 22 is formed in the semiconductor layer 21′. The well region 22 is located beneath the top surface 21a and is in contact with the top surface 21a in the vertical direction.

Then, referring to FIG. 5C, an STI region 25 is formed in the semiconductor layer 21′. In one embodiment, the STI region 25 is for example a shallow trench isolation (STI) structure. Please also refer to FIG. 2A. The STI region 25 is formed between the drain 29 and the body region 26, and the STI region 25 is in contact with the drain 29 in a channel direction (as indicated by the direction of the horizontal dashed arrow in FIG. 5C).

Subsequently, please refer to FIG. 5D. A drift oxide region 24 is formed on and in contact with the top surface 21a. The drift oxide region 24 is electrically insulative. The drift oxide region 24 is not limited to the LOCOS structure shown in FIG. 5D; in another embodiment, it can be a CVD oxide region. The drift oxide region 24 is located above and in contact with the drift region 22a (please refer to FIGS. 5D and 2A). The STI region 25 is located beneath the drift oxide region 24, and a part of the drift oxide region 24 is located vertically above a part of the STI region 25 and is in contact with the STI region 25. In one preferable embodiment, the drift oxide region 24 includes the CVD oxide region with a thickness of 400 Å-450 Å.

Then, please refer to FIG. 5E. The body region 26 is formed in the well region 22. The body region 26 is located beneath and in contact with the top surface 21a in the vertical direction. The body region 26 has the second conductivity type, which for example can be formed by: forming a photoresist layer 261 as a mask by a lithography process step and implanting impurities of the second conductivity type into the well region 22 in the form of accelerated ions in an ion implantation step, as indicated by the vertical dashed arrow in FIG. 5E.

Subsequently, please refer to FIG. 5F. The dielectric layer 273 and the conductive layer 271 of the gate 27 are formed on the top surface 21a of the semiconductor layer 21′ respectively, and a part of the body region 26 is located vertically beneath and in contact with the gate 27 in a vertical direction (as indicated by the direction of the dashed arrow in FIG. 5F), so as to provide an inversion current channel during the ON operation of the high voltage device 200.

Referring to FIGS. 5G and 2A, in one embodiment, after the dielectric layer 273 and the conductive layer 271 of the gate 27 are formed, a lightly doped region 282 is formed, so as to provide a conduction channel below the spacer layer 272 during the ON operation of the high voltage device 200; this is because the body region 26 beneath the spacer layer 272 cannot form the inversion current channel during the ON operation of the high voltage device 200. The lightly doped region 282 for example can be formed by implanting impurities of the first conductivity type into the body region 26 in the form of accelerated ions in an ion implantation step as indicated by the vertical dashed arrow in FIG. 5G. The portion of the lightly doped region 282 in the overlapped region between the lightly doped region 282 and the source 28 can be omitted because the concentration of the impurities of the first conductivity type in the lightly doped region 282 is far lower than that of the impurities of the first conductivity type in the source 28; for this reason, this portion of the lightly doped region 282 is also omitted in the following figures.

Still referring to FIG. 5G, a source 28 and a drain 29 are formed beneath the top surface 21a and in contact with the top surface 21a in the vertical direction. The source 28 and the drain 29 are located below the gate 27 respectively at two sides of the gate 27 in the channel direction; the source 28 is located in the body region 26, and the drain 29 is located in the well region 22 and away from the body region 26. The drift region 22a is located between the drain 29 and the body region 26 in the channel direction, in the well region 22 near the top surface 21a, to serve as a drift current channel of the high voltage device 200 during ON operation. The source 28 and the drain 29 have the first conductivity type. The source and the drain 29 may be formed by, for example but not limited to, forming a photoresist layer 281 as a mask by a lithography process step, and implanting impurities of the first conductivity type into the body region 26 and the well region 22 in the form of accelerated ions in an ion implantation process step as indicated by the vertical dashed arrow in FIG. 5G.

Then, as shown in FIG. 5H, spacer layers 272 are formed out of the lateral surface of the conductive layer 271, to complete the gate 27, so as to form the high voltage device 200.

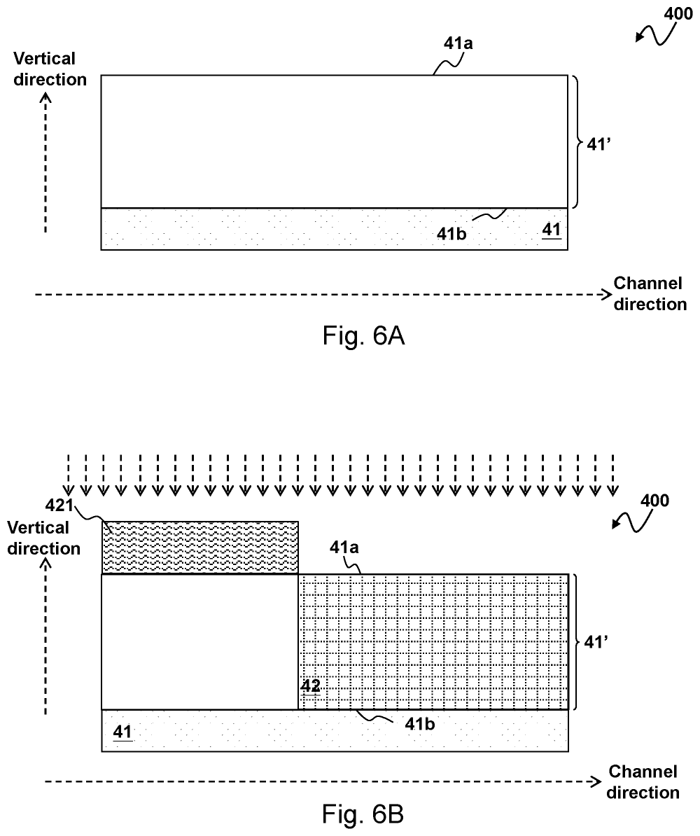

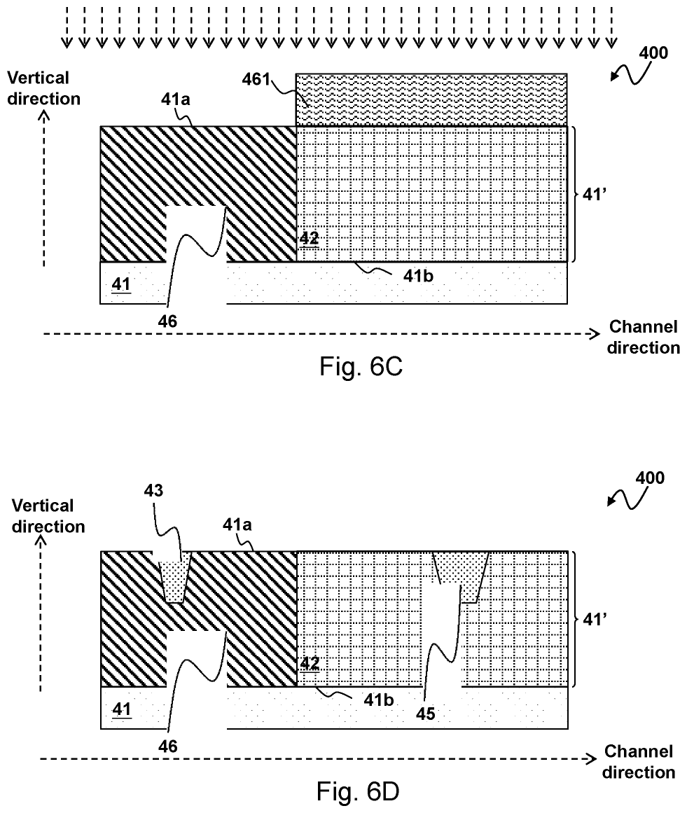

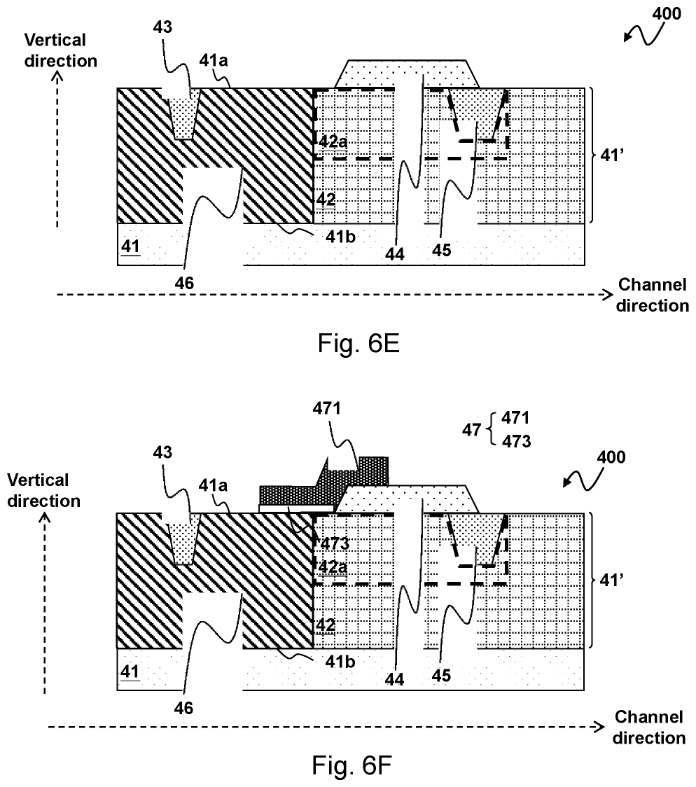

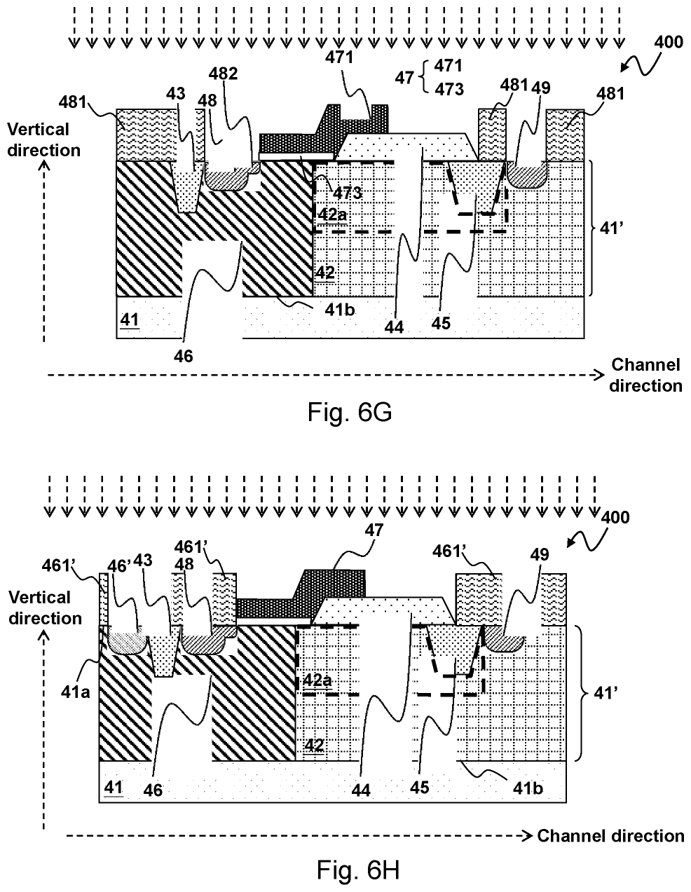

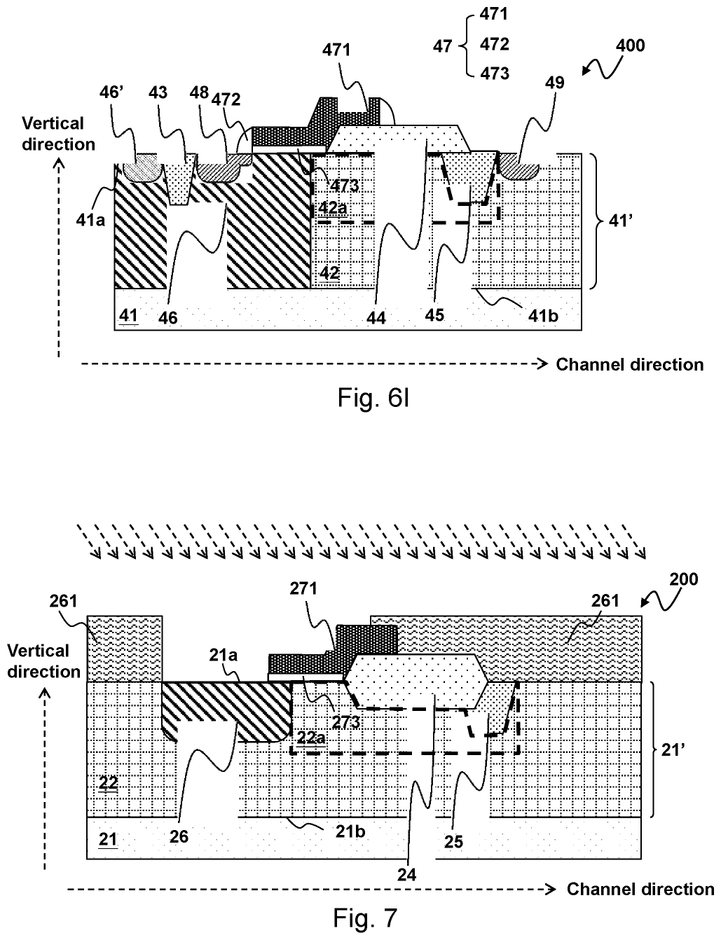

Please refer to FIGS. 6A-6I, which illustrate diagrams showing a method for manufacturing a high voltage control device 400 in accordance with another embodiment of the present invention. As shown in FIG. 6A, first, a semiconductor layer 41′ is formed on the substrate 41. A semiconductor layer 41′ is formed on the substrate 4 for example by an epitaxial process step, or the semiconductor layer 41′ is a part of the substrate 41. The semiconductor layer 41′ has a top surface 41a and a bottom surface 41b opposite to the top surface 41a in a vertical direction (as indicated by the direction of the dashed arrow in FIG. 6A). The semiconductor layer 41′ can be formed by various methods known to a person having ordinary skill in the art, so the details thereof are not redundantly explained here. The substrate 41 is, for example but not limited to, a P-type or N-type semiconductor substrate. In one preferable embodiment, the semiconductor layer 41′ is a P-type epitaxial silicon layer with a resistance of 45 Ohm-cm. In one preferable embodiment, the high voltage device 400 is a laterally diffused metal oxide semiconductor (LDMOS) device as shown in FIGS. 4A and 4B with a gate driving voltage of 3.3V and a gate oxide thickness of 80 Å-100 Å.

Subsequently, please refer to FIG. 6B. A drift well region 42 can be formed by, for example but not limited to, forming a photoresist layer 421 as a mask by a lithography process step and implanting impurities of the first conductivity type into the semiconductor layer 41′ in the form of accelerated ions in, for example but not limited to, one or more ion implantation process steps. The drift well region 42 is formed in the semiconductor layer 41′. The drift well region 42 is located beneath the top surface 41a and is in contact with the top surface 41a in the vertical direction.

Then, please refer to FIG. 6C. A channel well region 46 can be formed by, for example but not limited to, forming a photoresist layer 461 as a mask by a lithography process step and implanting impurities of the second conductivity type into the semiconductor layer 41′ in the form of accelerated ions in, for example but not limited to, one or more ion implantation process steps. At this stage, the drift oxide region 44 has not been formed yet, so the top surface 41a is not completely defined yet. The channel well region 46 is formed in the semiconductor layer 41′. The channel well region 42 is located beneath the top surface 41a and is in contact with the top surface 41a in the vertical direction. The drift well region 42 is in contact with the channel well region 46 in a channel direction (as indicated by the direction of the horizontal dashed arrow in FIG. 6C).

Subsequently, referring to FIG. 6D, at least one STI region 45 and a channel isolation region 43 are formed in the semiconductor layer 41′. In one embodiment, the STI region 45 is for example a shallow trench isolation (STI) structure. In one embodiment, the channel isolation region 43 is for example a shallow trench isolation (STI) structure. Please also refer to FIG. 4A. The STI region 45 is formed between the drain 49 and the channel well region 46, and the STI region 45 is in contact with the drain 49 in the channel direction. The channel isolation region 43 is formed between the source 48 and the channel well contact 46′.

Then, please refer to FIG. 6E. A drift oxide region 44 is formed on and in contact with the top surface 41a. The drift oxide region 44 is electrically insulative. The drift oxide region 44 is not limited to the CVD oxide region shown in FIG. 6E; in another embodiment, it can be a LOCOS structure. The drift oxide region 44 is located above and in contact with the drift region 42a (please refer to FIGS. 6E and 4A). The STI region 45 is located beneath the drift oxide region 44, and a part of the drift oxide region 44 is located vertically above a part of the STI region 45 and is in contact with the STI region 45. In one preferable embodiment, the drift oxide region 44 includes the CVD oxide region with a thickness of 400 Å-450 Å.

Subsequently, please refer to FIG. 6F. A dielectric layer 473 and a conductive layer 471 of the gate 47 are formed on the top surface 41a of the semiconductor layer 41′ respectively, and a part of the channel well region 46 is located vertically beneath and in contact with the gate 47 in a vertical direction (as indicated by the direction of the dashed arrow in FIG. 6F), so as to provide an inversion current channel during the ON operation of the high voltage control device 400.

Referring to FIGS. 6G and 4A, in one embodiment, after the dielectric layer 473 and the conductive layer 471 of the gate 47 are formed, a lightly doped region 482 is formed, so as to provide a conduction channel below the spacer layer 472 during the ON operation of the high voltage control device 400; this is because the channel well region 46 beneath the spacer layer 472 cannot form the inversion current channel during the ON operation of the high voltage control device 400. The lightly doped region 482 for example can be formed by implanting impurities of the first conductivity type into the channel well region 46 in the form of accelerated ions in, for example but not limited to, an ion implantation step as indicated by the vertical dashed arrow in FIG. 6G. The portion of the lightly doped region 482 in the overlapped region among the lightly doped region 482, the source 48 and the channel well contact 46′ can be omitted because the concentration of the impurities of the first conductivity type in the lightly doped region 482 is far lower than those of the impurities of the first conductivity type in the source 48 and the impurities of the second conductivity type in the channel well contact 46′. For this reason, such portion of the lightly doped region 482 is also omitted in the following figures.

Still referring to FIG. 6G, a source 48 and a drain 49 are formed beneath the top surface 41a and in contact with the top surface 41a in the vertical direction. The source 48 and the drain 49 are located below the gate 47 at two sides of the gate 47 respectively in the channel direction; the source 48 is located in the channel well region 46, and the drain 49 is located in the drift well region 42 and away from the channel well region 46. The drift region 42a is located between the drain 49 and the channel well region 46 in the channel direction, in the drift well region 42 near the top surface 41a, to serve as a drift current channel of the high voltage control device 400 during ON operation. The source 48 and the drain 49 have the first conductivity type. The source 48 and the drain 49 may be formed by, for example but not limited to, forming a photoresist layer 481 as a mask by a lithography process step, and implanting impurities of the first conductivity type into the channel well region 46 and the drift well region 42 respectively in the form of accelerated ions in, for example but not limited to, an ion implantation process step as indicated by the vertical dashed arrow in FIG. 6G.

Then, as shown in FIG. 6H, a channel well contact 46′ is formed in the channel well region 46 as the electrical contact of the channel well region 46. The channel well contact 46′ is formed beneath and in contact with the top surface 41a in the vertical direction. The channel well contact 46′ has the second conductivity type. The channel well contact 46′ may be formed by, for example but not limited to, forming a photoresist layer 461′ as a mask by a lithography process step, and implanting impurities of the second conductivity type into the channel well region 46 in the form of accelerated ions in, for example but not limited to, an ion implantation process step as indicated by the vertical dashed arrow in FIG. 6H.

Then, as shown in FIG. 6I, the spacer layers 472 are formed out of the lateral surface of the conductive layer 471, to complete the gate 47, so as to form the high voltage control device 400.

FIG. 7 illustrates a schematic diagram of forming the body region 26 of the high voltage device 200 in accordance with another embodiment of the present invention.

This embodiment is different from the embodiment shown in FIGS. 5A-5H in that, in this embodiment, the body region 26 is formed by a self-aligned process step, wherein the self-aligned process step includes: etching a poly silicon layer to form the conductive layer 271 of the gate 27; and using the conductive layer 271 as a mask and forming the body region 26 by an ion implantation step. The steps of this embodiment which are the same as the embodiment shown in FIGS. 5A-5H are omitted in the following description.

As shown in FIG. 7, the dielectric layer 273 and the conductive layer 271 of the gate 27 are formed. Methods of forming the dielectric layer 273 and the conductive layer 271 for example include: etching a silicon dioxide layer and a poly silicon layer to form the dielectric layer 273 and the conductive layer 271 respectively; next, using the conductive layer 271 as a mask, or as shown in FIG. 7, further providing the photoresist layer 261 as the mask, the body region 26 is formed by implanting impurities of the second conductivity type into the well region 22 in the form of accelerated ions in an ion implantation step, as indicated by the tilted dashed arrow in FIG. 7. Note that, in order to form part of the body region 26 below the gate 27, the incident direction of the accelerated ions needs to be tilted at a predetermined angle with respect to the normal direction of the well region 22, so that a part of the second conductivity type impurities are implanted below the gate 27.

Advantages of the present invention which are better than the prior art include that: according to the present invention, taking the embodiment shown in FIGS. 2A and 2B as an example, the conduction resistance of the high voltage device 200 can be reduced and the breakdown voltage of the high voltage device 200 can be enhanced by disposing the STI region 25 in the drift region 22a at the drain 29 side of the high voltage device 200 in cooperation with the drift oxide region 24 above the STI region 25. Furthermore, the high voltage device 200 of the present invention can be manufactured by a standard high voltage device manufacturing process without the need of an additional lithography process step, whereby the manufacturing cost does not increase as compared to the prior art.

The present invention has been described in considerable detail with reference to certain preferred embodiments thereof. It should be understood that the description is for illustrative purpose, not for limiting the broadest scope of the present invention. Those skilled in this art can readily conceive variations and modifications within the spirit of the present invention. For example, other process steps or structures, such as a deep well, may be added. For another example, the lithography technique is not limited to the mask technology but it can be electron beam lithography, etc. The various embodiments described above are not limited to being used alone; two embodiments may be used in combination, or a part of one embodiment may be used in another embodiment. Therefore, in the same spirit of the present invention, those skilled in the art can think of various equivalent variations and modifications, which should fall in the scope of the claims and the equivalents.

What is claimed is:

1. A high voltage device comprising:
a semiconductor layer formed on a substrate;
a well region having a first conductivity type, wherein the well region is formed in the semiconductor layer;
a shallow trench isolation (STI) region formed in the semiconductor layer;
a drift oxide region formed on the semiconductor layer, wherein the STI region is located beneath the drift oxide region, and a part of the drift oxide region is located vertically above a part of the STI region and is in contact with the STI region, wherein the drift oxide region is located above a drift region;
a body region having a second conductivity type, wherein the body region is formed in the semiconductor layer, and the body region is in contact with the well region in a channel direction;
a gate formed on the semiconductor layer, wherein a part of the body region is located vertically beneath and in contact with the gate, so as to provide an inversion current channel during an ON operation of the high voltage device, and a part of the gate is located vertically above and in contact with the drift oxide region; and
a source and a drain having the first conductivity type, wherein the source and the drain are formed in the semiconductor layer, wherein the source and the drain are located below the gate at two sides of the gate respectively, wherein the source is located in the body region, and the drain is located in the well region and away from the body region, wherein the drift region is located in the well region between the drain and the body region in the channel direction and serves as a drift current channel during the ON operation of the high voltage device;
wherein the STI region is formed between the drain and the body region.

2. The high voltage device of claim 1, wherein the drift oxide region includes a local oxidation of silicon (LOCOS) structure or a chemical vapor deposition (CVD) oxide region.

3. The high voltage device of claim 1, wherein the STI region is in contact with the drain in the channel direction.

4. The high voltage device of claim 1, wherein the semiconductor layer is a P-type epitaxial silicon layer with a resistance of 45 Ohm-cm.

5. The high voltage device of claim 2, wherein the drift oxide region includes the CVD oxide region with a thickness of 400 Å-450 Å.

6. The high voltage device of claim 1, wherein the high voltage device is a laterally diffused metal oxide semiconductor (LDMOS) device with a gate driving voltage of 3.3V and a gate oxide thickness of 80 Å-100 Å.

7. The high voltage device of claim 6, wherein a low voltage device is formed on the substrate, and the low voltage device has a channel length of 0.18 μm.

8. The high voltage device of claim 6, wherein the body region is formed by a self-aligned process step, wherein the self-aligned process step includes: etching a poly silicon layer to form a conductive layer of the gate; and using the conductive layer as a mask and forming the body region by an ion implantation step.

9. A method for manufacturing a high voltage device, the method comprising:
forming a semiconductor layer on a substrate;
forming a well region in the semiconductor layer, wherein the well region has a first conductivity type;
forming at least one shallow trench isolation (STI) region in the semiconductor layer;
forming a drift oxide region on the semiconductor layer, wherein the STI region is located beneath the drift oxide region, and a part of the drift oxide region is located vertically above a part of the STI region and is in contact with the STI region, wherein the drift oxide region is located above a drift region;
forming a body region having a second conductivity type in the semiconductor layer, wherein the body region is in contact with the well region in a channel direction;
forming a gate on the semiconductor layer, wherein a part of the body region is located vertically beneath and in contact with the gate, so as to provide an inversion current channel during an ON operation of the high voltage device, and a part of the gate is located vertically above and in contact with the drift oxide region; and
forming a source and a drain in the semiconductor layer, wherein the source and the drain are located below the gate at two sides of the gate respectively, wherein the source is located in the body region, and the drain is located in the well region and away from the body region, wherein the drift region is located in the well region between the drain and the body region in the channel direction and serves as a drift current channel during the ON operation of the high voltage device;
wherein the STI region is formed between the drain and the body region.

10. The method of claim 9, wherein the drift oxide region includes a local oxidation of silicon (LOCOS) structure or a chemical vapor deposition (CVD) oxide region.

11. The method of claim 9, wherein the STI region is in contact with the drain in the channel direction.

12. The method of claim 9, wherein the semiconductor layer is a P-type epitaxial silicon layer with a resistance of 45 Ohm-cm.

13. The method of claim 10, wherein the drift oxide region includes the CVD oxide region with a thickness of 400 Å-450 Å.

14. The method of claim 9, wherein the high voltage device is a laterally diffused metal oxide semiconductor (LDMOS) device with a gate driving voltage of 3.3V and a gate oxide thickness of 80 Å-100 Å.

15. The method of claim 14, wherein a low voltage device is formed on the substrate, and the low voltage device has a channel length of 0.18 μm.

16. The method of claim 9, wherein the body region is formed by a self-aligned process step, wherein the self-aligned process step includes: etching a poly silicon layer to form a conductive layer of the gate; and using the conductive layer as a mask and forming the body region by an ion implantation step.

17. A high voltage control device comprising:
a semiconductor layer formed on a substrate;
a drift well region having a first conductivity type, wherein the drift well region is formed in the semiconductor layer;
a channel well region having a second conductivity type, wherein the channel well region is formed in the semiconductor layer, and the channel well region is in contact with the drift well region in a channel direction;
a shallow trench isolation (STI) region formed in the semiconductor layer;
a drift oxide region formed on the semiconductor layer, wherein the STI region is located beneath the drift oxide region, and a part of the drift oxide region is located vertically above a part of the STI region and is in contact with the STI region, wherein the drift oxide region is located above a drift region;
a gate formed on the semiconductor layer, wherein a part of the channel well region is located vertically beneath and in contact with the gate, so as to provide an inversion current channel during an ON operation of the high voltage control device, and a part of the gate is located vertically above and in contact with the drift oxide region;
a source and a drain having the first conductivity type, wherein the source and the drain are formed in the semiconductor layer, wherein the source and the drain are located below the gate at two sides of the gate respectively, wherein the source is located in the channel well region, and the drain is located in the drift well region and away from the channel well region, wherein the drift region is located in the drift well region between the drain and the channel well region in the channel direction and serves as a drift current channel during the ON operation of the high voltage control device;
a channel well contact having the second conductivity type, wherein the channel well contact is formed in the channel well region and serves as an electrical contact of the channel well region, wherein the channel well contact is formed beneath and in contact with a top surface of the semiconductor layer in a vertical direction; and
a channel isolation region formed in the semiconductor layer and between the source and the channel well contact, wherein the channel isolation region is formed beneath and in contact with the top surface;
wherein the STI region is formed between the drain and the channel well region.

18. The high voltage control device of claim 17, wherein the drift oxide region includes a local oxidation of silicon (LOCOS) structure or a chemical vapor deposition (CVD) oxide region.

19. The high voltage control device of claim 17, wherein the STI region is in contact with the drain in the channel direction.

20. The high voltage control device of claim 17, wherein the semiconductor layer is a P-type epitaxial silicon layer with a resistance of 45 Ohm-cm.

21. The high voltage control device of claim 18, wherein the drift oxide region includes the CVD oxide region with a thickness of 400 Å-450 Å.

22. The high voltage control device of claim 17, wherein the high voltage device is a laterally diffused metal oxide semiconductor (LDMOS) device with a gate driving voltage of 3.3V and a gate oxide thickness of 80 Å-100 Å.

23. The high voltage control device of claim 22, wherein a low voltage device is formed on the substrate, and the low voltage device has a channel length of 0.18 μm.

24. A method for manufacturing a high voltage control device, the method comprising:
forming a semiconductor layer on a substrate;
forming a drift well region in the semiconductor layer, wherein the drift well region has a first conductivity type;
forming a channel well region having a second conductivity type in the semiconductor layer, wherein the channel well region is in contact with the drift well region in a channel direction;
forming at least one shallow trench isolation (STI) region in the semiconductor layer and forming a channel isolation region in the semiconductor layer, wherein the channel isolation region is formed beneath and in contact with a top surface of the semiconductor layer;
forming a drift oxide region on the semiconductor layer, wherein the STI region is located beneath the drift oxide region, and a part of the drift oxide region is located vertically above a part of the STI region and is in contact with the STI region, wherein the drift oxide region is located above a drift region;
forming a gate on the semiconductor layer, wherein a part of the channel well region is located vertically beneath and in contact with the gate, so as to provide an inversion current channel during an ON operation of the high voltage control device, and a part of the gate is located vertically above and in contact with the drift oxide region;
forming a source and a drain in the semiconductor layer, wherein the source and the drain are located below the gate at two sides of the gate respectively, wherein the source is located in the channel well region, and the drain is located in the drift well region and away from the channel well region, wherein the drift region is located in the drift well region between the drain and the channel well region in the channel direction and serves as a drift current channel during the ON operation of the high voltage control device; and
forming a channel well contact in the channel well region, wherein the channel well contact has the second conductivity type and serves as an electrical contact of the channel well region, wherein the channel well contact is formed beneath and in contact with the top surface in a vertical direction;
wherein the STI region is formed between the drain and the channel well region, wherein the channel isolation region is formed between the source and the channel well contact.

25. The method of claim 24, wherein the drift oxide region includes a local oxidation of silicon (LOCOS) structure or a chemical vapor deposition (CVD) oxide region.

26. The method of claim 24, wherein the STI region is in contact with the drain in the channel direction.

27. The method of claim 24, wherein the semiconductor layer is a P-type epitaxial silicon layer with a resistance of 45 Ohm-cm.

28. The method of claim 25, wherein the drift oxide region includes the CVD oxide region with a thickness of 400 Å-450 Å.

29. The method of claim 24, wherein the high voltage device is a laterally diffused metal oxide semiconductor (LDMOS) device with a gate driving voltage of 3.3V and a gate oxide thickness of 80 Å-100 Å.

30. The method of claim 29, wherein a low voltage device is formed on the substrate, and the low voltage device has a channel length of 0.18 μm.
